(19) United States
(12) Patent Application Publication
(10) Pub. No.: US 2020/0287002 A1
(43) Pub. Date: Sep. 10, 2020

(54) SEMICONDUCTOR COMPOUND, SEMICONDUCTOR DEVICE AND LAMINATE HAVING LAYER OF SEMICONDUCTOR COMPOUND, AND TARGET

(71) Applicants: AGC Inc., Chiyoda-ku (JP); TOKYO INSTITUTE OF TECHNOLOGY, Meguro-ku (JP)

(72) Inventors: Hideo HOSONO, Tokyo (JP); Junghwan Kim, Tokyo (JP); Joonho Bang, Tokyo (JP); Hideya Kumomi, Tokyo (JP); Satoru Watanabe, Tokyo (JP); Kazuto Ohkoshi, Tokyo (JP); Naomichi Miyakawa, Tokyo (JP); Nao Ishibashi, Tokyo (JP); Kunio Masumo, Tokyo (JP); Nobuhiro Nakamura, Tokyo (JP)

(73) Assignees: AGC Inc., Chiyoda-ku (JP); TOKYO INSTITUTE OF TECHNOLOGY, Meguro-ku (JP)

(21) Appl. No.: 16/878,937

(22) Filed: May 20, 2020

Related U.S. Application Data
(63) Continuation of application No. PCT/JP2018/040243, filed on Oct. 30, 2018.

(30) Foreign Application Priority Data
Nov. 28, 2017 (JP) 2017-228022

(51) Int. Cl. H01L 29/24; H01L 29/786; H01L 21/02; H01L 29/66; C23C 14/34; C23C 14/08; C01G 19/00; H01J 37/34

(52) U.S. Cl. CPC H01L 29/247; H01L 29/78693; H01L 21/02592; H01L 21/02565; H01L 21/02631; H01L 29/66969; H01J 2237/332; C23C 14/086; C01G 19/006; H01J 37/3426; C01P 2006/40; C01P 2002/72; C01P 2002/52; C23C 14/3407

(57) ABSTRACT

An oxide-based semiconductor compound including metal cations and oxygen, wherein hydride ions H⁻ originally bonded with the metal cations have been replaced with fluorine ions F⁻ and at least one of the fluorine ions F⁻ is bonded with one to three of the metal cations.

### CROSS-REFERENCE TO RELATED APPLICATION

The present application is a continuation application filed under 35 U.S.C. 111 (a) claiming benefit under 35 U.S.C. 120 and 365 (c) of PCT International Application No. PCT/JP2018/040343 filed on Oct. 30, 2018 and designating the U.S., which claims priority to Japanese Patent Application No. 2017-228022 filed on Nov. 28, 2017. The entire contents of the foregoing applications are incorporated herein by reference.

### BACKGROUND OF THE INVENTION

### 1. Field of the Invention

The present invention relates to a semiconductor compound, a semiconductor device and a laminate having a layer of such a semiconductor compound, and a target for deposition constituted by such a semiconductor compound.

### 2. Description of the Related Art

Conventionally, for example, silicon has been widely used as a semiconductor material in semiconductor devices such as thin film transistors (TFTs).

Recently, it has become known that, among oxide semiconductors containing metal cations, there are compounds with relatively wide optical band gaps and relatively high mobilities, and it has been attempted to apply such oxide semiconductors to semiconductor devices.

Among them, oxide semiconductors such as ZnO and In—Ga—Zn—O are transparent and have characteristics comparable to amorphous silicon and low-temperature polysilicon, and are expected to be applied to next-generation TFTs (for example, PTL 1).

### PRIOR ART DOCUMENT

### Patent Literature

PTL 1: Publication of Japanese Patent No. 5589030
PTL 2: Japanese Laid-Open Patent Publication No. 2007-115902

### SUMMARY OF THE INVENTION

### Technical Problem

As described above, oxide semiconductor compounds are expected to be applied to semiconductor devices as a substitute for silicon.

However, it is known that the characteristics of oxide semiconductor compounds such as In—Ga—Zn—O-based oxides fluctuate under illumination stress. Such a fluctuation in characteristics becomes a problem when oxide semiconductor compounds are applied to various semiconductor devices.

For example, when a conventional oxide semiconductor compound is used as a driving device for a liquid crystal panel, visible light from the backlight and/or external light including ultraviolet light can illuminate the oxide semiconductor compound. Also, when a conventional oxide semiconductor compound is used as a driving device for an OLED (organic light emitting diode) panel, the oxide semiconductor compound may be irradiated with light generated by light emission. In such an illumination stress, for example, an increase in the leak current may occur in the oxide semiconductor compound. In addition, this may cause problems such as a decrease in the contrast of the liquid crystal panel and the OLED panel.

Therefore, in order to deal with such a problem, a conventional oxide semiconductor compound is provided in a semiconductor device with a light shielding layer shielding light (for example, PTL 2).

If such a fluctuation in characteristics of the oxide semiconductor compound under illumination stress can be reduced, there is no need to provide a light shielding layer, and as a result, the degree of flexibility in the configuration of the semiconductor device is expected to dramatically increase.

The present invention has been made in view of such circumstances, and it is an object of the present invention to provide a semiconductor compound in which a fluctuation in characteristics can be reduced significantly under the illumination stress explained above. In addition, it is an object of the present invention to provide a semiconductor device and a laminate having a layer of the above-described semiconductor compound. In addition, it is an object of the present invention to provide a target for deposition constituted by the above-described semiconductor compound.

### Solution to Problem

According to the present invention, provided is an oxide-based semiconductor compound including metal cations and oxygen,
wherein hydride ions H⁻ originally bonded with the metal cations have been replaced with fluorine ions and
at least one of the fluorine ions F⁻ is bonded with one to three of the metal cations.

Further, according to the present invention, provided is a semiconductor compound including:
gallium, zinc, and oxygen;
at least one of tin, aluminum, titanium, and indium, the semiconductor compound further including:
fluorine.

Still further, according to the present invention, provided is a semiconductor device including a layer of a semiconductor compound,
wherein the semiconductor device is any one of a TFT (thin-film transistor), a photovoltaic cell, and an OLED (organic light emitting diode), and
the layer is constituted by the semiconductor compound having the above-described feature.

Still further, according to the present invention, provided is a laminate including:
a substrate;
a layer of a semiconductor compound arranged on or above the substrate,
wherein the layer is constituted by the semiconductor compound having the above-described feature.

Still further, according to the present invention, provided is a target for deposition, including:
the semiconductor compound having the above-described feature.

Still further, according to the present invention, provided is a semiconductor compound including:
gallium, zinc, and oxygen; and
at least one of tin, aluminum, titanium, and indium,
wherein an atomic ratio of gallium atoms with respect to all cationic atoms is in a range of 10% to 40%.

### Effect of Invention

According to the present invention, a semiconductor compound in which a fluctuation in characteristics can be reduced significantly under illumination stress can be provided. In addition, a semiconductor device and a laminate having a layer of the above semiconductor compound can be provided. In addition, a target for deposition constituted by the above semiconductor compound can be provided.

### BRIEF DESCRIPTION OF THE DRAWINGS

FIG. 1 is a drawing schematically illustrating a cross section of a thin-film transistor according to an embodiment of the present invention.

FIG. 2 is a drawing schematically illustrating a cross section of another thin-film transistor according to an embodiment of the present invention.

FIG. 3 is a drawing schematically illustrating a step of production of a thin-film transistor according to an embodiment of the present invention.

FIG. 4 is a drawing schematically illustrating a step of production of a thin-film transistor according to an embodiment of the present invention.

FIG. 5 is a drawing schematically illustrating a step of production of a thin-film transistor according to an embodiment of the present invention.

FIG. 6 is a drawing schematically illustrating a step of production of a thin-film transistor according to an embodiment of the present invention.

FIG. 7 is a drawing schematically illustrating a step of production of a thin-film transistor according to an embodiment of the present invention.

FIG. 8 is a drawing schematically illustrating a step of production of a thin-film transistor according to an embodiment of the present invention.

FIG. 9 is a drawing schematically illustrating a cross section of a photovoltaic cell according to an embodiment of the present invention.

FIG. 10 is a drawing schematically illustrating a cross section of an organic light emitting diode according to an embodiment of the present invention.

FIG. 11 is a chart illustrating an X-ray diffraction measurement result obtained with a first glass substrate sample.

FIG. 12 is a cross sectional view schematically illustrating a configuration of a TFT sample 1.

FIG. 13 is a drawing illustrating a characteristics evaluation result under illumination by a white LED light source, obtained with the TFT sample 1.

FIG. 14 is a drawing illustrating a characteristics evaluation result under illumination by a white LED light source, obtained with a TFT sample of a conventional configuration.

FIG. 15 is a graph expressing a threshold voltage difference ΔVₜₕ, obtained with each TFT sample, as a function of a content of Ga (atomic %) included in a semiconductor layer.

FIG. 16 is a graph illustrating a result of hydride ion H⁻ concentration evaluation (FTIR) of two types of films produced in Example 7.

FIG. 17 is a graph illustrating a result of OH concentration evaluation (FTIR) of two types of films produced in Example 7.

FIG. 18 is a graph illustrating light absorption characteristics of the two types of films produced in Example 7.

FIG. 19 is a drawing illustrating a characteristics evaluation result under illumination by a white LED light source, obtained with the TFT sample 7.

FIG. 20 is a drawing illustrating a characteristics evaluation result under illumination by a white LED light source, obtained with a TFT sample according to a comparative example.

FIG. 21 is a graph illustrating a result of FTIR with two types of films produced in Example 8.

FIG. 22 is a drawing illustrating a characteristics evaluation result under illumination by a white LED light source obtained with a TFT sample 8-1.

FIG. 23 is a drawing illustrating a characteristics evaluation result under illumination by a white LED light source, obtained with a TFT sample 8-2.

FIG. 24 is a graph illustrating a light absorption spectrum of each film produced in Example 9.

FIG. 25 is a drawing illustrating a characteristics evaluation result under illumination by a white LED light source, obtained with a TFT sample 9-1.

### DETAILED DESCRIPTION OF THE PREFERRED EMBODIMENTS

Hereinafter, an embodiment of the present invention will be described.

(Semiconductor Compound According to an Embodiment of the Present Invention)

According to an embodiment of the present invention, provided is an oxide-based semiconductor compound including metal cations and oxygen,
wherein hydride ions H⁻ bonded with the metal cations have been replaced with fluorine ions and
at least one of the fluorine ions F⁻ is bonded with one to three of the metal cations.

Further, according to an embodiment of the present invention, provided is an oxide-based semiconductor compound including:
gallium, zinc, and oxygen; and
at least one of tin, aluminum, titanium, and indium, further including fluorine.

When such a semiconductor compound is applied to a semiconductor device such as a TFT, a change in characteristics due to the presence or absence of illumination stress can be significantly reduced as described in detail below. For example, a leak current under illumination stress can be significantly reduced.

Also, even when a negative voltage is applied to a semiconductor device having a semiconductor compound according to an embodiment of the present invention under illumination stress (hereinafter such an environment is referred to as “negative bias illumination stress (NBIS)”), voltage-current characteristics of the semiconductor device are less likely to change. Therefore, in a case where the semiconductor compound according to the embodiment of the present invention is applied to the semiconductor device, an additional layer such as the conventional light shielding layer is not required, and the degree of flexibility in the configuration can be significantly increased.

A phenomenon in which a threshold voltage shifts negatively under NBIS is widely observed in conventional oxide semiconductors in both crystalline and amorphous states. For example, this phenomenon is observed in crystalline ZnO, amorphous In—Zn—O, Zn—Sn—O, In—Ga—Zn—O, In—Sn—Zn—O, and Hf—In—Zn—O.

The mechanism for instability of these oxide semiconductors under NBIS is as follows:
(i) A subgap state is formed near the valence band in the bandgap.
(ii) The subgap state is excited by illumination stress, and the generated electrons go to the conduction band, and holes remain in the subgap state.
(iii) Under the negative gate voltage, the generated holes move toward an interface between the gate insulating film and the oxide semiconductor, and shift the threshold voltage to a negative voltage.

The inventors of the present application have reported that the above subgap state is a level formed by hydride ions H⁻ bonded with metal cations in the oxide semiconductor (as to the details, see J. Bang, S. Matsuishi, H. Hosono etc., Appl. Phys. Lett., vol. 110, 232105 (2017)). The energy level of the bonding between a metal cation and a hydride ion H⁻ has the maximum density of states at an energy of 0.4 eV with respect to the upper end of the valence band being 0 eV, and is formed in the band gap. In the case of amorphous IGZO, the number of metal ions bonded with this hydride ion (coordination number) is 1 to 3.

The inventors of the present application have reported that, in the amorphous IGZO, a hydroxide ion OH⁻ in which the hydrogen is partially positively charged and a hydride ion H⁻ in which the hydrogen is negatively charged exist as chemical states of the hydrogen. The inventors have reported that the concentrations thereof are about 1.5×10²⁰ cm⁻³ (about 0.2 atom %) and about 7.6×10¹⁹ cm⁻³ (about 0.1 atom %), respectively. Among them, the hydroxide ions OH⁻ can be removed by heat treatment at 600 degrees Celsius or higher, but even with such treatment being performed, the instability under NBIS is not significantly improved. In contrast, the hydride ions which form the subgap state, are reduced by about 30% by the heat treatment at 600 degrees Celsius or higher, at which crystallization starts, but 70% of the hydride ions H⁻ still remain.

As a method of removing the hydride ions (H⁻), it is conceivable to remove moisture and hydrogen gas contained in the vacuum chamber, but these gases are likely to remain in vacuum, and it is very difficult to practically remove these gases. In a case where the concentration of hydride ions H⁻ is reduced, oxygen defects are newly generated in the oxide semiconductor, and a new subgap state occurs at an energy of 1.1 eV. Such oxygen defects react with moisture during processes such as, for example, post-annealing, and form bonds between metal cations and hydride ions again, causing instability under NBIS. Furthermore, when the concentration of hydride ions H⁻ is reduced, metal-metal bonds are newly generated in the oxide semiconductor, and a new defect energy level is formed in the band gap.

According to the present invention, an oxide semiconductor in which hydride ions have been replaced with fluorine ions F⁻ is provided as a solution for removing hydride ions (H⁻) and not generating oxygen defects. According to the present invention, an oxide semiconductor having bonding between metal cation(s) M and a fluorine ion F⁻ is provided. According to the present invention, the number (coordination number) of metal cations M bonded with the fluorine ion is 1 to 3.

According to the present invention, an oxide-based (oxyfluoride) semiconductor compound is provided, in which the concentration of fluorine ions is equal to or more than 1×10¹⁷ cm⁻³, and the concentration of hydride ions is equal to or less than 5×10¹⁹ cm⁻³.

The metal constituting the above bonding is preferably gallium, zinc, tin, or indium. The energy level of the bonding between the metal cations and fluorine ion F⁻ has a negative energy with respect to the upper end of the valence band being 0 eV. Therefore, the energy level is not formed in the band gap, and a subgap state does not occur.

The bonding between a metal cation M and a fluorine ion F⁻ is more thermally stable than the bonding between a metal cation M and a hydride ion H⁻. With the bonding between the metal cation M and the fluorine ion F⁻, oxygen defects and metal-metal bonds are less likely to occur in a production step of TFT, such as film deposition, heat treatment, plasma treatment, or electrode formation.

Examples of methods for introducing fluorine into a semiconductor compound include:
(i) a method of mixing a fluorine compound with a sputter target,
(ii) a method of introducing a fluorine gas into a film deposition gas,
(iii) a method in which fluorine is introduced into the gate insulating film in advance and thermally diffused into the semiconductor compound by reheating after a TFT is produced, and
(iv) a method by ion implantation.

Of these methods, the methods (i) and (ii) are preferable because a semiconductor compound having high homogeneity in the depth direction and in the in-plane direction can be obtained in a short time. Using these methods, the fluorine compound or the fluorine gas is activated during deposition, resulting in a semiconductor compound having fluorine ions bonded with the above metal cations. In addition, moisture and hydrogen concentration in the deposition atmosphere can be reduced, which is preferable. As the fluorine compound, CaF₂, MgF₂, GaF₃, ZnF₂, SnF₄, InF₃, LaF₃, and the like can be used. In particular, when CaF₂ or MgF₂ is used, the fluorine compound does not readily decompose during production of a target, and the sintering density is improved, and further, it is easy to control the fluorine content, which is preferable. Further, when LaF₃ is used, the fluorine compound does not readily decompose during production of a target, and the sintering density is improved. Further, it becomes easy to control the fluorine content.

Among them, in the methods (iii) and (iv), the TFT cannot be produced in a short time, and it is difficult to control the concentration of fluorine, and the semiconductor compound becomes ununiform.

In a semiconductor compound according to an embodiment of the present invention, the reason why a change in characteristics is reduced under illumination stress is as follows:
1. Reduction of hydride ions by formation of bonding between metal cations and fluorine ions,
2. Reduction of the subgap state by reduction of hydride ions, and
3. Reduction of generation of oxygen defects or metal-metal bonds, due to bonding between metal cations and fluorine ions being thermally stable.

(Composition of Semiconductor Compound According to Embodiment of the Present Invention)

Subsequently, an example of a composition of a semiconductor compound according to an embodiment of the present invention will be explained.

A semiconductor compound according to an embodiment of the present invention (hereinafter simply referred to as “first compound”) is constituted by an oxide-based compound including:
(i) gallium (Ga), zinc (Zn), and oxygen (O),
(ii) at least one of tin (Sn), aluminum (Al), titanium (Ti), and indium (In), and
(iii) fluorine (F).

Hereinafter, in the first compound, the elements included in the above (i) are particularly referred to as “essential elements”, and the elements included in the above (ii) are particularly referred to as “optional elements”.

Herein, a term “oxide-based” is used to mean that the first compound in this application primarily includes an oxide and further includes fluorine. In other words, “oxide-based” means a compound in which most of the anions are constituted by oxygen but which include a small amount of anions other than oxygen.

In the first compound, gallium is preferably included at a range of 10 atom % to 40 atom % with respect to all the cationic species. The gallium is more preferably included at a range of 10 atom % to 35 atom % with respect to all the cationic species. The gallium is still more preferably included at a range of 13 atom % to 27 atom % with respect to all the cationic species.

In the first compound, the zinc is preferably included at a range of 20 atom % to 62 atom % with respect to all the cationic species. The zinc is more preferably included at a range of 49 atom % to 62 atom % with respect to all the cationic species. The zinc is still more preferably included at a range of 54 atom % to 60 atom % with respect to all the cationic species.

In the first compound, the fluorine is preferably included at a range of 0.001 mol % to 2 mol %.

The first compound preferably includes tin or indium as an “optional element”. In a case where the first compound includes tin as the “optional element”, the tin is preferably included at a range of 10 atom % to 35 atom % with respect to all the cationic species. The tin is more preferably included at a range of 15 atom % to 29 atom % with respect to all the cationic species.

In a case where the first compound includes indium as the “optional element”, the indium is preferably included at a range of 10 atom % to 40 atom % with respect to all the cationic species.

It is preferable that the first compound is substantially constituted by the elements (i) to (iii).

However, in practice, the first compound may include unavoidable materials (metal, semiconductor, and/or compound) not shown in the above (i) to (iii). Most of such unavoidable materials are considered to be introduced during the production process of the first compound. A term “substantially constituted by” means a possible inclusion of such unavoidable materials.

It is preferable that the first compound includes as few hydride ions (H⁻) as possible. This is because the hydride ions (H⁻) included in the first compound may affect the subgap state of the first compound (as to the details, see J. Bang, S. Matsuishi, H. Hosono etc., Appl. Phys. Lett., vol. 110, 232105 (2017)).

For example, the concentration of hydride ions (H⁻) is preferably equal to or less than 5×10¹⁹ cm⁻³. It should be noted that the concentration of hydride ions (H⁻) can be measured by infrared spectroscopy.

In the first compound, the OH concentration is preferably equal to or less than 1×10²¹ cm⁻³. The hydroxide ions OH⁻ are not directly involved in formation of the subgap state, but when the OH concentration is more than 1×10²¹ cm⁻³, the density of the film may decrease, and the semiconductor characteristics may decrease. The OH concentration is preferably equal to or less than 1×10²⁰ cm⁻³.

The first compound may be amorphous or may be dominantly in an amorphous state.

Here, the term “amorphous” refers to a substance that does not produce a sharp peak in X-ray diffraction measurement. Specifically, the term “amorphous” means a substance of which crystallite diameter (Scherrer diameter) determined by the Scherrer equation represented by the following equation (1) is 6.0 nm or less. Where the Scherrer constant is denoted as K, an X-ray wavelength is denoted as λ, a half width is denoted as β, and a peak position is denoted as θ, a Scherrer diameter L is given by the following equation.

L=Kλ/(β cos θ) Expression (1)

For example, when the X-ray wavelength λ is 0.154 nm, the Scherrer constant K becomes 0.9.

In contrast, a phrase “dominantly in amoLphous state” means a state in which amorphousness exists at more than 50% by volume.

When the first compound is amorphous or dominantly in the amorphous state, defect energy levels at grain boundaries cause less influence, and the electrical characteristics vary less greatly. The first compound may be microcrystalline or in a form in which amorphous and microcrystalline states exist in a mixed manner.

Herein, a microcrystal is a crystal of which Scherrer diameter is more than 6.0 nm and less than 100 nm. It is preferable that the first compound is microcrystalline because it improves the conductivity. It is preferable that the first compound is in a form in which amorphous and microcrystalline states exist in a mixed manner because both smoothness and conductivity are improved.

(Composition of Semiconductor Compound According to Another Embodiment of the Present Invention)

Another embodiment of the present invention is provided as a semiconductor compound including gallium, zinc, and oxygen, and including at least one of tin, aluminum, titanium, and indium, wherein an atomic ratio of gallium atoms with respect to all cationic atoms is in a range of 10% to 40%.

More preferably, the gallium is included at a range of 10 atom % to 35 atom % with respect to all cationic species. Still more preferably, the gallium is included at a range of 13 atom % to 27 atom % with respect to all cationic species.

The zinc is preferably included at a range of 20 atom % to 62 atom % with respect to all cationic species. The zinc is more preferably included at a range of 49 atom % to 62 atom % with respect to all cationic species. The zinc is still more preferably included at a range of 54 atom % to 60 atom % with respect to all cationic species.

The semiconductor compound preferably includes tin or indium, and in a case where the semiconductor compound includes tin as the “optional element”, the tin is preferably included at a range of 10 atom % to 35 atom % with respect to all cationic species. The tin is more preferably included at a range of 15 atom % to 29 atom % with respect to all cationic species.

In a case where the semiconductor compound includes indium as the “optional element”, the indium is preferably included at a range of 10 atom % to 40 atom % with respect to all cationic species.

(Example of Application of Semiconductor Compound According to Embodiment of the Present Invention)

The first compound having the above feature can be applied to various semiconductor devices such as, for example, a thin-film transistor (TFT), a photovoltaic cell, an organic light emitting diode (OLED), and the like. An example of such a semiconductor device will be explained more specifically with reference to drawings.

(Thin-Film Transistor)

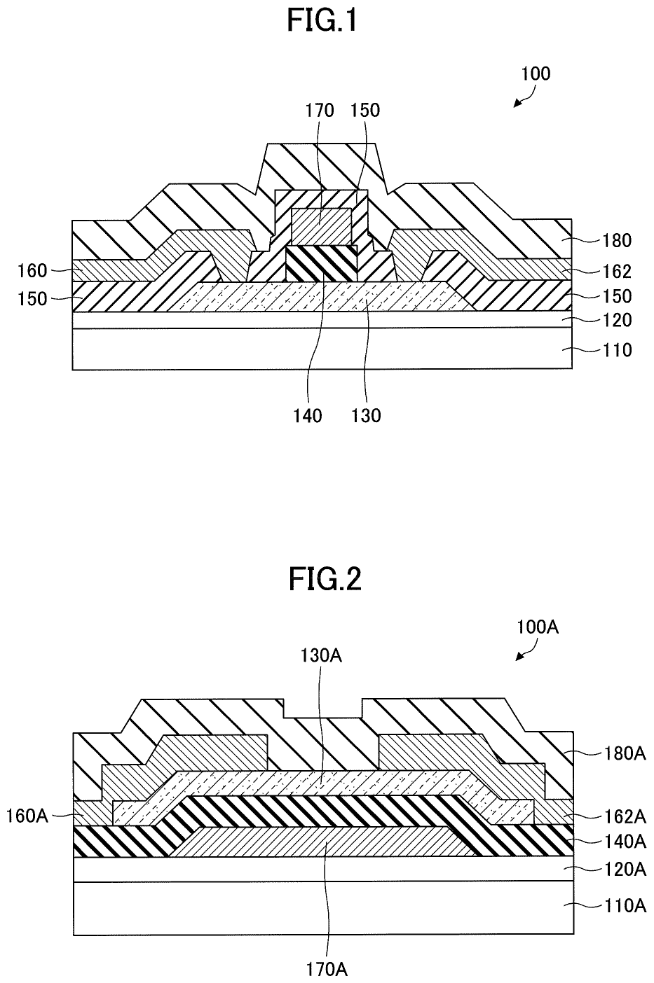

FIG. 1 schematically illustrates a cross section of a thin-film transistor according to an embodiment of the present invention (hereinafter referred to as a “first semiconductor device”).

As illustrated in FIG. 1, a first semiconductor device 100 is constituted by arranging, on a substrate 110, layers, i.e., a barrier film 120, a semiconductor layer 130, a gate insulating film 140, an interlayer insulating film 150, a first electrode (a source or a drain) 160, a second electrode (a drain or a source) 162, a gate electrode 170, and a passivation film 180.

The substrate 110 is an insulating substrate such as, for example, a glass substrate, a ceramic substrate, a plastic substrate, a resin substrate, or the like. The substrate 110 may be a transparent substrate.

The barrier film 120 is arranged between the substrate 110 and the semiconductor layer 130, and is configured to form a back channel interface between the substrate 110 and the semiconductor layer 130. The barrier film 120 is constituted by, for example, silicon oxide, silicon oxynitride, silicon nitride, alumina, and the like. The barrier film 120 is not an essential component, and may be omitted if it is not necessary.

The gate insulating film 140 is constituted by inorganic insulating materials such as, for example, silicon oxide, silicon oxynitride, silicon nitride, and alumina. The same applies to the interlayer insulating film 150.

The first and second electrodes 160, 162, as well as the gate electrode 170 are constituted by a metal, such as for example, aluminum, copper, and silver, or other conductive materials.

The passivation film 180 is configured to protect the device, and is constituted by, for example, silicon oxide, silicon oxynitride, silicon nitride, alumina, and the like.

Here, in the first semiconductor device 100, the semiconductor layer 130 is constituted by the first compound having the above-described characteristics.

In a conventional TFT, a semiconductor compound (hereinafter, referred to as “IGZO compound”) such as, for example, In—Ga—Zn—O has been used as a semiconductor layer.

However, as described above, the IGZO compound exhibits changes in its characteristics according to whether there is illumination stress or not. For this reason, for example, in a conventional TFT that includes IGZO compound as a semiconductor layer, the leak current increases under illumination stress as compared to the leak current without illumination stress. In addition, such a TFT not only increases the leak current under the negative bias illumination stress, but also, in some cases, shifts the threshold voltage in the negative direction, which may make it impossible to perform the OFF operation.

Due to such a problem, in a conventional TFT including an IGZO compound as a semiconductor layer, in a case where the substrate 110 is transparent in the configuration illustrated in FIG. 1, it is desired to provide a light shielding layer under the semiconductor layer 130, e.g., between the substrate 110 and the barrier film 120, in order to prevent the semiconductor layer 130 from being irradiated with light. Depending on the size of the gate electrode 170, it is desired to provide another light shielding layer at an upper side of the semiconductor layer 130, in order to prevent the semiconductor layer 130 from being irradiated with light. Here, the light shielding layer means a pattern layer which is made of metal or resin to shield incident light, and which is not electrically connected to the electrodes of the semiconductor devices, and means a layer that blocks incident light.

Such a light shielding layer not only complicates the structure of the semiconductor device and the production process of the semiconductor device, but also results in a problem of significantly restricting the degree of flexibility in the configuration of the semiconductor device.

In contrast, as the semiconductor layer 130, the first compound having the above-described feature is applied to the first semiconductor device 100. In this case, changes in its characteristics according to whether there is illumination stress or not can be significantly reduced. For example, even when the first semiconductor device 100 is used under negative bias illumination stress, the changes in its characteristics can be significantly reduced.

Therefore, in the first semiconductor device 100, there is no need to add a light shielding layer as in the conventional case, and the structure of the semiconductor device and the production process can be simplified. Accordingly, in the first semiconductor device 100, the degree of flexibility in the configuration can be significantly increased.

The semiconductor layer 130 can be produced by a pulse laser deposition method or a sputtering method. By using these methods, films with less defects can be obtained, and carriers can be generated even at a deep donor level. In addition, under the illumination stress or the negative bias illumination stress, the carrier generation due to a defect energy level is reduced, so that the increase in the leak current and the shift in the threshold voltage in the negative direction can be alleviated.

In the example of the first semiconductor device 100 as illustrated in FIG. 1, the semiconductor layer 130 is arranged between the substrate 110 and the gate electrode 170.

However, as another example of a thin-film transistor according to an embodiment of the present invention, a what is termed as an “inverted staggered configuration” as illustrated in FIG. 2 is also conceivable.

As illustrated in FIG. 2, a thin-film transistor 100A is constituted by arranging, on a substrate 110A, layers, i.e., a barrier film 120A, a gate electrode 170A, a gate insulating film 140A, a semiconductor layer 130A, a first electrode (a source or a drain) 160A, a second electrode (a drain or a source) 162A, and a passivation film 180A.

According to such a configuration, even in a case where the above-described first compound is applied to the semiconductor layer 130A, it is not necessary to provide a light shielding layer in a portion of the semiconductor layer 130A that is not covered by the first electrode 160A and the second electrode 162A.

(Production Method of Thin-Film Transistor)

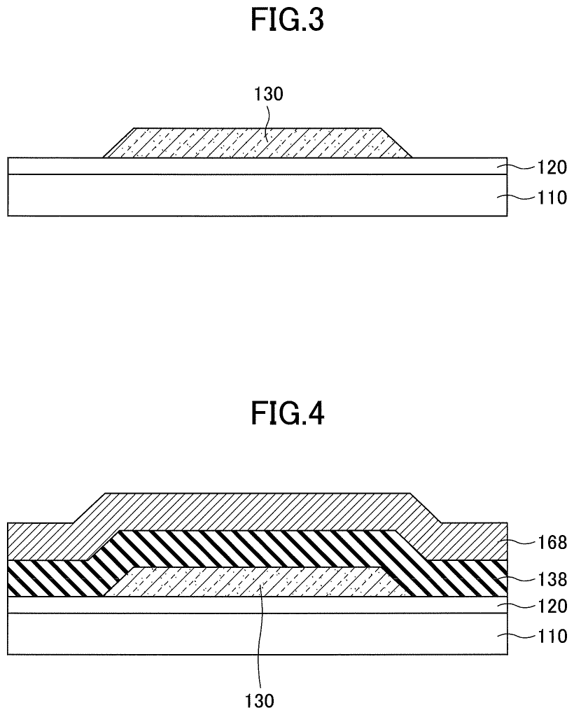

Subsequently, a method of producing the first semiconductor device 100 as illustrated in FIG. 1 will be described with reference to FIGS. 3 to 8.

When the first semiconductor device 100 is produced, first, the substrate 110 is prepared.

As described above, the substrate 110 may be, for example, a transparent insulating substrate such as a glass substrate, a ceramic substrate, a plastic (for example, polycarbonate or polyethylene terephthalate) substrate, a resin substrate, or the like. The substrate 110 is used after being thoroughly washed.

Next, if necessary, the barrier film 120 is formed on one of the surfaces of the substrate 110.

As described above, the barrier film 120 may be constituted by silicon oxide, silicon oxynitride, silicon nitride, alumina, and the like. Alternatively, a material having an ultraviolet absorbing function, such as zinc oxide, may be used as the barrier film 120. In this case, ultraviolet light entering the first semiconductor device 100 can be absorbed.

The method for forming the barrier film 120 is not particularly limited. The barrier film 120 may be deposited using various deposition techniques such as, for example, a sputtering method, a pulse laser deposition method, an atmospheric pressure CVD method, a low pressure CVD method, and a plasma CVD method. The thickness of the barrier film 120 is, for example, in a range of 10 nm to 500 nm.

As described above, the barrier film 120 is a layer provided as necessary, and may be omitted.

Subsequently, the semiconductor layer 130 is formed on the barrier film 120 (in a case where the barrier film 120 does not exist, the semiconductor layer 130 is formed on the substrate 110).

The semiconductor layer 130 is constituted by the above-described first compound. The semiconductor layer 130 is deposited using various deposition techniques such as, for example, a sputtering method, a pulse laser deposition method, an atmospheric pressure CVD method, a low pressure CVD method, and a plasma CVD method.

In a case where the semiconductor layer 130 is deposited by a sputtering method, for example, a target constituted by the above-described first compound is used as a target. In this case, a deposition environment may be a low oxygen partial pressure environment (for example, a reduced pressure environment).

Alternatively, the semiconductor layer 130 may be deposited by a sputtering method in an atmosphere containing fluorine (for example, an atmosphere including F₂ gas). In this case, a compound not including fluorine, i.e., a target including the above-described essential element (i) and the optional element (ii) may be used as the target.

It should be noted that the deposition of the semiconductor layer 130 may be performed continuously with the deposition of the barrier film 120 using an apparatus used for the deposition of the barrier film 120.

The thickness of the semiconductor layer 130 is preferably in a range of 10 nm to 90 nm. In a case where the thickness is 10 nm or more, a sufficient accumulation electron layer can be formed. The thickness of the semiconductor layer 130 is more preferably equal to or more than 20 nm, and still more preferably equal to or more than 30 nm. When the thickness of the semiconductor layer 130 is equal to or less than 90 nm, the voltage consumption in the thickness direction can be disregarded. The thickness of the semiconductor layer 130 is more preferably equal to or less than 80 nm, and still more preferably equal to or less than 60 nm.

Subsequently, the semiconductor layer 130 is patterned to form a desired pattern.

Examples of methods for patterning processing of the semiconductor layer 130 include generally-available methods such as, for example, a mask deposition method and a lift-off method. Another method for patterning processing includes arranging an island-shaped resist pattern on an upper portion of the semiconductor layer 130 after the semiconductor layer 130 is deposited, and etching the semiconductor layer 130 using the resist pattern as a mask.

In a case where the semiconductor layer 130 is etched, examples of etchants that can be applied include an aqueous solution of hydrochloric acid, an aqueous solution of EDTA (ethylenediamine tetraacetic acid), and an aqueous solution of TMAH (tetramethyl ammonium hydride).

After the semiconductor layer 130 is patterned, the semiconductor layer 130 is preferably annealed. The annealing atmosphere is selected from, e.g., air, reduced pressure air, oxygen, hydrogen, inert gas such as nitrogen, argon, helium, and neon, and further from water vapor. The annealing temperature is preferably from 100 degrees Celsius to 400 degrees Celsius. When the annealing temperature is 400 degrees Celsius or lower, the field effect mobility of the semiconductor layer 130 becomes uniform. The annealing temperature is more preferably equal to or less than 350 degrees Celsius, and still more preferably equal to or less than 300 degrees Celsius.

FIG. 3 schematically illustrates a state in which the barrier film 120 and the patterned semiconductor layer 130 are arranged on the substrate 110.

In addition, the intermediate member as illustrated in FIG. 3, i.e., a laminate having the semiconductor layer 130 on or above the substrate 110, can be used not only as the first semiconductor device 100 but also in various fields as intermediates for various apparatuses and devices.

Such a laminate may or may not have the barrier film 120, and the semiconductor layer 130 may or may not be patterned.

Subsequently, as illustrated in FIG. 4, an insulating film 138 and a conductive film 168 are successively arranged on the semiconductor layer 130.

The insulating film 138 is constituted by a material that will later become the gate insulating film 140. For example, the insulating film 138 may be constituted by silicon oxide, silicon oxynitride, silicon nitride, alumina, and the like. The insulating film 138 may be constituted using various deposition techniques such as, for example, a sputtering method, a pulse laser deposition method, an atmospheric pressure CVD method, a low pressure CVD method, and a plasma CVD method.

The thickness of the insulating film 138 is preferably 30 nm to 600 nm. When the thickness of the insulating film 138 is equal to or more than 30 nm, a short-circuit is less likely to occur between the gate electrode 170 and the semiconductor layer 130, between the gate electrode 170 and the first electrode (the source or the drain) 160, or between the gate electrode 170 and the second electrode (the drain or the source) 162. When the thickness of the insulating film 138 is equal to or less than 600 nm, a high ON current can be obtained. The thickness of the insulating film 138 is more preferably equal to or more than 50 nm, and still more preferably equal to or more than 150 nm. The thickness of the insulating film 138 is more preferably equal to or less than 500 nm, and still more preferably equal to or less than 400 nm.

The conductive film 168 is constituted by a material that will later become the gate electrode 170. For example, the conductive film 168 is made of chromium (Cr), molybdenum (Mo), aluminum (Al), copper (Cu), silver (Ag), tantalum (Ta), titanium (Ti), or composite materials and/or alloys including the afore-mentioned materials. The conductive film 168 may be a laminated film.

In the first semiconductor device 100, as described above, there is no need to shield the semiconductor layer 130 from light. Therefore, a transparent conductive film may be used as the conductive film 168. Examples of such transparent conductive films include ITO (In—Sn—O), ZnO, AZO (Al—Zn—O), GZO (Ga—Zn—O), IZO (In—Zn—O), and SnO₂.

The conductive film 168 may be deposited by a conventional deposition method such as a sputtering method and a vapor deposition method. Further, the insulating film 138 and the conductive film 168 may be continuously deposited by the same deposition apparatus.

The thickness of the conductive film 168 is preferably 30 nm to 600 nm. When the thickness of the conductive film 168 is equal to or more than 30 nm, a low resistance is obtained, and when the thickness is equal to or less than 600 nm, a short-circuit is less likely to occur between the conductive film 168 and the first electrode (the source or the drain) 160 or between the conductive film 168 and the second electrode (the drain or the source) 162. The thickness of the conductive film 168 is more preferably equal to or more than 50 nm, and still more preferably equal to or more than 150 nm. The thickness of the conductive film 168 is more preferably equal to or less than 500 nm, and still more preferably equal to or less than 400 nm.

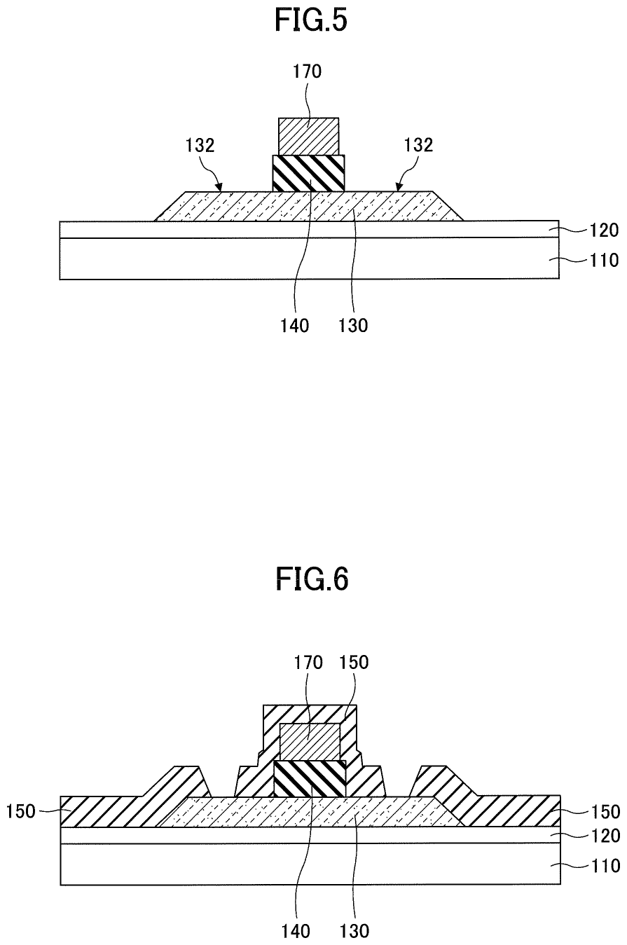

Subsequently, as illustrated in FIG. 5, the insulating film 138 and the conductive film 168 are patterned, and as a result, each of the gate insulating film 140 and the gate electrode 170 is formed.

For the patterning processing of the insulating film 138 and the conductive film 168, a method generally used for TFT array process, i.e., a combination of a photolithography process and etching process, may be used.

After the pattern processing of both layers is completed, a process of reducing the electrical resistance of a protruding portion 132 (see FIG. 5) protruding, in a plan view, from the gate electrode 170 of the semiconductor layer 130 may be performed, i.e., resistance reduction processing may be performed. The resistance reduction processing may be performed by, for example, a method for performing hydrogen plasma treatment on the protruding portion 132 or a method for injecting hydrogen ions into the protruding portion 132.

With the resistance reduction processing of the protruding portion 132, the ON-resistance of the TFT can be reduced.

Subsequently, the interlayer insulating film 150 is formed on the laminated film. As described above, the interlayer insulating film 150 may be constituted by silicon oxide, silicon oxynitride, silicon nitride, alumina, and the like. The interlayer insulating film 150 is deposited with generally-available deposition techniques such as, for example, a sputtering method, a pulse laser deposition method, an atmospheric pressure CVD method, a low pressure CVD method, and a plasma CVD method.

As illustrated in FIG. 6, the insulating film 150 is patterned on both sides of the gate electrode 170 so that parts of the protruding portion 132 of the semiconductor layer 130 are exposed. A combination of a generally-available photolithography process and a generally-available etching process may be used for patterning processing of such an interlayer insulating film.

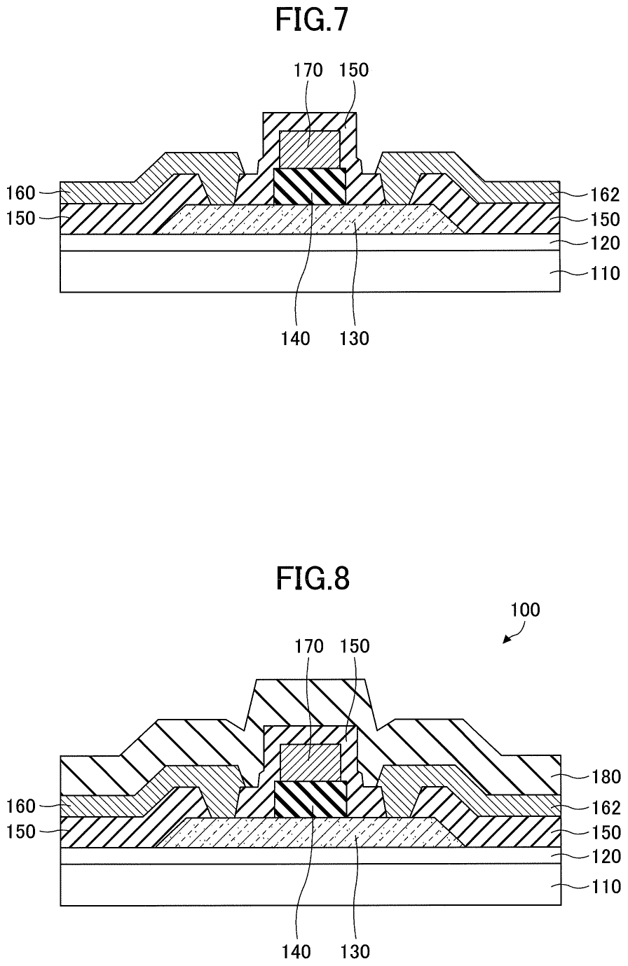

Subsequently, as illustrated in FIG. 7, the first electrode 160 and the second electrode 162 are arranged and patterned. The first and second electrodes 160, 162 are, for example, a drain electrode and a source electrode, respectively, or a source electrode and a drain electrode, respectively.

The first electrode 160 and the second electrode 162 are arranged and patterned so as to make ohmic contact with at least a part of the protruding portion 132 of the semiconductor layer 130. A combination of a generally-available photolithography process and a generally-available etching process may be used for patterning processing of the first electrode 160 and the second electrode 162.

The first electrode 160 and the second electrode 162 may be made of chromium, molybdenum, aluminum, copper, silver, tantalum, titanium, or composite materials and/or alloys including the afore-mentioned materials. The first electrode 160 and the second electrode 162 may be a laminated film. Alternatively, like the gate electrode 170, the first electrode 160 and the second electrode 162 may be transparent conductive films.

Subsequently, as illustrated in FIG. 8, the passivation film 180 is formed so as to cover a laminated film. The passivation film 180 may be constituted by silicon oxide, silicon oxynitride, silicon nitride, and the like.

The passivation film 180 may be deposited with deposition techniques such as, for example, a sputtering method, a pulse laser deposition method, an atmospheric pressure CVD method, a low pressure CVD method, and a plasma CVD method.

The thickness of the passivation film 180 is preferably 30 nm to 600 nm. When the thickness of the passivation film 180 is equal to or more than 30 nm, the exposed electrode can be covered, and when the thickness of the passivation film 180 is equal to or less than 600 nm, the deflection of the substrate 110 due to film stress becomes smaller. The thickness of the passivation film 180 is more preferably equal to or more than 50 nm, and still more preferably equal to or more than 150 nm. The thickness of the passivation film 180 is more preferably equal to or less than 500 nm, and still more preferably equal to or less than 400 nm.

Through the above steps, the first semiconductor device 100 can be produced.

It should be noted that the above producing method is merely an example, and it is apparent to those skilled in the art that the first semiconductor device 100 may be produced by another method. For example, when a liquid crystal or organic electroluminescent array is driven with the first semiconductor device 100, auxiliary capacitance wiring, terminals, and/or current compensation circuits may be formed in addition to the above films.

(Photovoltaic Cell)

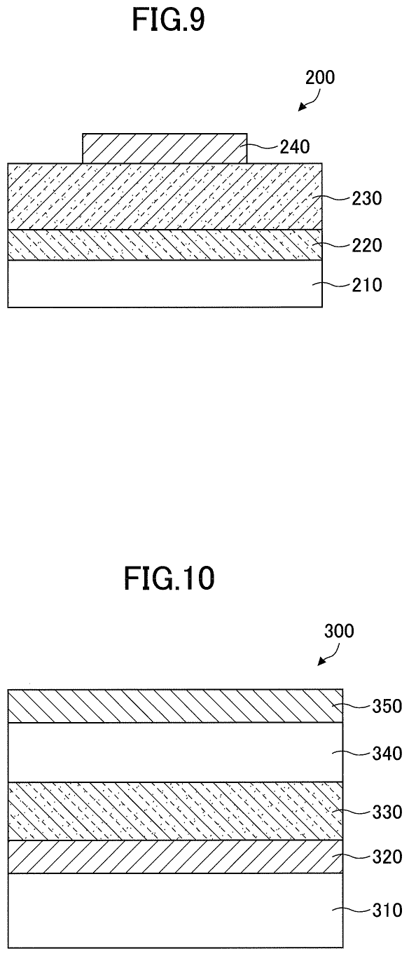

Subsequently, a configuration of a photovoltaic cell according to an embodiment of the present invention will be explained with reference to FIG. 9.

FIG. 9 schematically illustrates a cross section of a photovoltaic cell (hereinafter referred to as a “second semiconductor device”) according to an embodiment of the present invention.

As illustrated in FIG. 9, a second semiconductor device 200 is constituted by arranging, on a support body 210, layers, i.e., a silicon layer 220, a semiconductor layer 230, and an electrode layer 240.

The support body 210 is configured to support the layers on top of the support body 210. The support body 210 may be constituted by a transparent insulating substrate such as, for example, a glass substrate, a ceramic substrate, a plastic (for example, polycarbonate or polyethylene terephthalate) substrate, or a resin substrate.

The electrode layer 240 is made of a conductive material such as a metal.

The production method for producing the second semiconductor device 200 can be easily understood by referring to the production method for producing the first semiconductor device 100 explained above. Therefore, herein, the explanation about the production method for producing the second semiconductor device 200 is omitted.

Herein, in the second semiconductor device 200, the semiconductor layer 230 is constituted by the above-described first compound.

Therefore, with the second semiconductor device 200, the effects as explained above can be obtained, i.e., the effect of significantly reducing changes in its characteristics according to whether there is illumination stress or not can be obtained. For example, even when the second semiconductor device 200 is used under negative bias illumination stress, changes in its characteristics can be significantly reduced.

(Organic Light Emitting Diode)

Subsequently, a configuration of an organic light emitting diode (OLED) according to an embodiment of the present invention will be explained with reference to FIG. 10.

FIG. 10 schematically illustrates a cross section of an OLED (hereinafter referred to as a “third semiconductor device”) according to an embodiment of the present invention.

As illustrated in FIG. 10, the third semiconductor device 300 is constituted by arranging, on a substrate 310, layers, i.e., a first electrode (cathode) 320, a semiconductor layer 330, an organic layer 340, and a second electrode (anode) 350, which are arranged in the above order.

The substrate 310 is configured to support the layers on top of the substrate 310. The substrate 310 may be constituted by a transparent insulating substrate such as, for example, a glass substrate, a ceramic substrate, a plastic (for example, polycarbonate or polyethylene terephthalate) substrate, or a resin substrate.

The semiconductor layer 330 has a function of an electron injection layer or an electron transport layer.

The organic layer 340 includes not only an organic light-emitting layer but also an electron injection layer, an electron transport layer, an organic light-emitting layer, a hole transport layer, a hole injection layer, and the like. However, each layer other than the organic light-emitting layer may be omitted if it is not necessary.

In the example of FIG. 10, a surface at the same side as the substrate 310 serves as a light-extraction surface. Therefore, the substrate 310 is a transparent substrate, the first electrode 320 is a transparent electrode, and the semiconductor layer 330 is a transparent layer.

The production method for producing the third semiconductor device 300 can be easily understood by referring to the production method for producing the first semiconductor device 100 explained above. Therefore, herein, the explanation about the production method for producing the third semiconductor device 300 is omitted.

Herein, in the third semiconductor device 300, the semiconductor layer 330 is constituted by the above-described first compound.

Therefore, with the third semiconductor device 300, the effects as explained above can be obtained, i.e., the effect of significantly reducing changes in its characteristics according to whether there is illumination stress or not can be obtained. For example, even when the third semiconductor device 300 is used under negative bias illumination stress, changes in its characteristics can be significantly reduced.

(Target for Deposition)

The semiconductor compound according to an embodiment of the present invention can also be applied to a target for deposition.

Specifically, according to an embodiment of the present invention, provided is a target for deposition, including:
an oxide-based semiconductor compound,
wherein the oxide-based semiconductor compound includes:
gallium, zinc, and oxygen;
at least one of tin, aluminum, titanium, and indium; and
fluorine.

The gallium included in the target is included at a range of 10 atom % to 40 atom % with respect to all cationic species. More preferably, the gallium is included at a range of 10 atom % to 35 atom % with respect to all cationic species. Still more preferably, the gallium is included at a range of 13 atom % to 27 atom % with respect to all cationic species.

The zinc included in the target is preferably included at a range of 20 atom % to 62 atom % with respect to all cationic species. The zinc is more preferably included at a range of 49 atom % to 62 atom % with respect to all cationic species. The zinc is still more preferably included at a range of 54 atom % to 60 atom % with respect to all cationic species.

The fluorine included in the target is preferably in a range of 0.001 mol % to 2 mol %.

The target preferably includes tin or indium as an “optional element”. In a case where the first compound includes tin as the “optional element”, the tin is preferably included at a range of 10 atom % to 35 atom % with respect to all the cationic species. The tin is preferably included at a range of 15 atom % to 29 atom % with respect to all the cationic species.

In a case where the target includes indium as the “optional element”, the indium is preferably included at a range of 10 atom % to 40 atom % with respect to all the cationic species.

It should be noted that the target may include unavoidable materials (metal, semiconductor, and/or compound) as explained above.

In a case where a film is formed on a substrate by a sputtering method using such a target, a thin film of a semiconductor compound having the above-described feature can be obtained.

The application form of the first compound has been described above with reference to the TFT, the photovoltaic cell, the OLED, and the target for deposition.

It should be noted that these are merely examples, and it is apparent to those skilled in the art that the first compound can be applied to other apparatuses or devices. Examples of such devices include Bio-FET (field effect transistor) sensors.

### EXAMPLES

Subsequently, Examples of the present invention will be explained.

### Example 1

(Evaluation of Semiconductor Compound Film)

According to the following method, an oxide-based semiconductor compound including Ga, Zn, Sn, and F is deposited, and the characteristics thereof were evaluated.

First, the target for sputtering deposition was produced.

The target was prepared as follows:

A mixed powder was prepared by weighing and mixing Ga₂O₃ powder, ZnO powder, and SnO₂ powder, so that a cation atom % ratio of Ga:Zn:Sn becomes 13.3:60:26.7. Further, 1 mol % of calcium fluoride (CaF₂ powder) was added to this powder to prepare a mixed powder.

Subsequently, a green compact was formed from the obtained mixed powder. Then, the green compact was fired to obtain a sintered body having a diameter of 50.8 mm and a height of 5 mm (hereinafter referred to as a “first sintered body”).

Using the first sintered body as the target, the thin film was deposited on the substrate by a sputtering method. A quartz glass substrate was used as the substrate.

The deposition condition is as follows.

Deposition atmosphere: mixed gas of Ar and O₂, with a concentration of O₂ being 0.35%

Pressure of deposition gas: 1 Pa

Applied power: RF 200 W

Distance between substrate and target: 10 cm

As a result, on the substrate, an oxide-based film including Ga, Zn, Sn, and F and having a thickness of about 168 nm was formed. Hereinafter the obtained laminate is referred to as a “first glass substrate sample”.

The film obtained according to the above deposition method is referred to as a “film 1”.

Subsequently, the crystalline property of the film 1 was evaluated.

The evaluation of the crystalline property was performed by X-ray diffraction measurement of the first glass substrate sample. D2-Phaser of Bruker Corporation was used as a measurement apparatus.

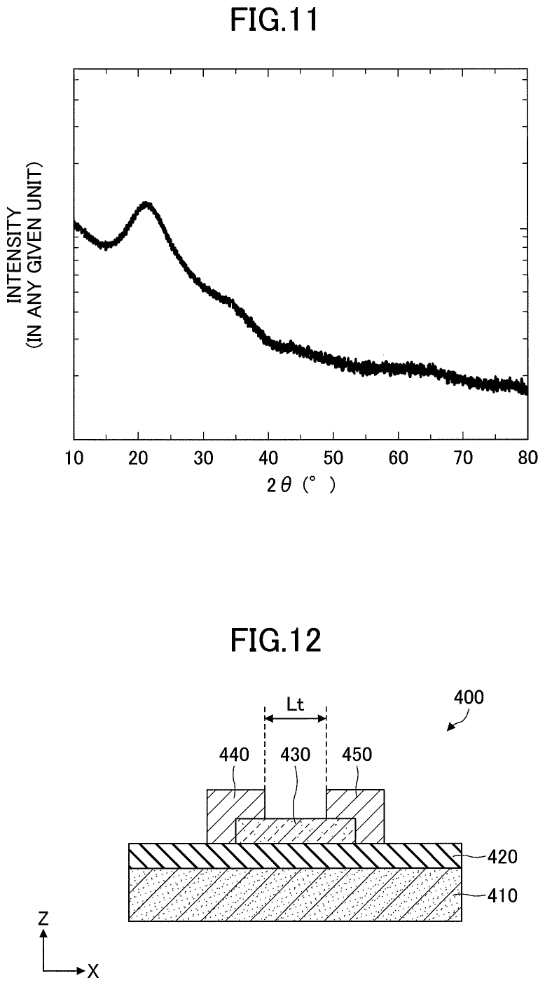

FIG. 11 illustrates an X-ray diffraction measurement result obtained with the first glass substrate sample. From this result, it was found that, with the first glass substrate sample, only a broad halo pattern was recognized. Therefore, it was found that the film 1 was amorphous.

(Production of TFT Sample)

Subsequently, a TFT device (hereinafter referred to as a “TFT sample 1”) was produced according to the following method.

FIG. 12 schematically illustrates a cross sectional configuration of the TFT sample 1.

As illustrated in FIG. 12, a TFT sample 1 400 included a silicon substrate 410, a thermal oxidation film 420, a semiconductor layer 430, a drain electrode 440, and a source electrode 450.

In order to produce the TFT sample 1 400 described above, first, the silicon substrate 410 (13 mm×13 mm) attached with the thermal oxidation film 420 was prepared. The silicon substrate 410 was n-type, and had a specific resistance of 0.001 Ωcm. The thermal oxidation film 420 was formed by oxidizing the silicon substrate 410. The thickness of the thermal oxidation film 420 was 150 nm.

The silicon substrate 410 was used as a gate electrode for the TFT sample 1 400, and the thermal oxidation film 420 was used as a gate insulating film for the TFT sample 1 400.

Subsequently, a photoresist was arranged on the thermal oxidation film 420. This photoresist was patterned by a generally-available photolithography method. At the center of the photoresist pattern, there was a rectangular hole area of 900 μm in length×300 μm in width (i.e., a distance in the X direction of FIG. 12).

Subsequently, using a photoresist as a mask, a semiconductor layer was formed on the thermal oxidation film 420 by a sputtering method.

The semiconductor layer was deposited under the same conditions as the deposition condition for the above-described film 1. However, the thickness of the semiconductor layer was set to 50 nm.

Thereafter, the silicon substrate 410 was immersed in acetone and cleaned with ultrasonic cleaning for 5 minutes. Further, ultrasonic cleaning was performed in ethanol for minutes. As a result, the photoresist and the semiconductor layer deposited on the photoresist were removed. As a result, the island-shaped semiconductor layer 430 was formed at a central portion of the thermal oxidation film 420.

Subsequently, the silicon substrate 410 was annealed at 400 degrees Celsius for 1 hour under the atmosphere.

Subsequently, the drain electrode 440 and the source electrode 450 in the form as illustrated in FIG. 12 were formed on the thermal oxidation film 420 and the semiconductor layer 430.

These electrodes 440 and 450 were made of metal aluminum, and formed by a generally-available sputtering method using the above-described photoresist pattern as a mask.

In a plan view, the dimensions of the drain electrode 440 and the source electrode 450 were 300 μm in length×200 μm in width (i.e., a distance in the X direction of FIG. 12)×50 nm in thickness (maximum portion). A distance Lt between the drain electrode 440 and the source electrode 450 (see FIG. 12) was set to 50 μm.

Finally, the end surface of the silicon substrate 410 was polished to expose the conductive surface, and the exposed surface was used as an energizing portion.

Through the above steps, the TFT sample 1 400 was produced. It is clear from the above description that the semiconductor layer 430 of the TFT sample 1 400 corresponds to the above-described “film 1”.

(Evaluation of TFT Sample 1)

Characteristics evaluation was performed under the negative bias illumination stress by using the TFT sample 1 400 produced as described above.

Specifically, in the state where the TFT sample 1 400 was irradiated with light from the side opposite to the silicon substrate 410 and a negative voltage was applied to the gate electrode (the silicon substrate 410), a change in the characteristics that occurred in the TFT sample 1 400 was measured.

A semiconductor parameter analyzer (4155C: Agilent Technologies, Inc.) was used to measure the change in the characteristics. A white LED light source was used as a light source. The illuminance of the white LED light source was 11000 Lux.

During characteristics evaluation, under illumination stress of the light source, the gate electrode was set to −10 V, and the drain electrode 440 and the source electrode 450 were set to 0 V, which were maintained for a certain period of time, and thereafter, a measurement was performed.

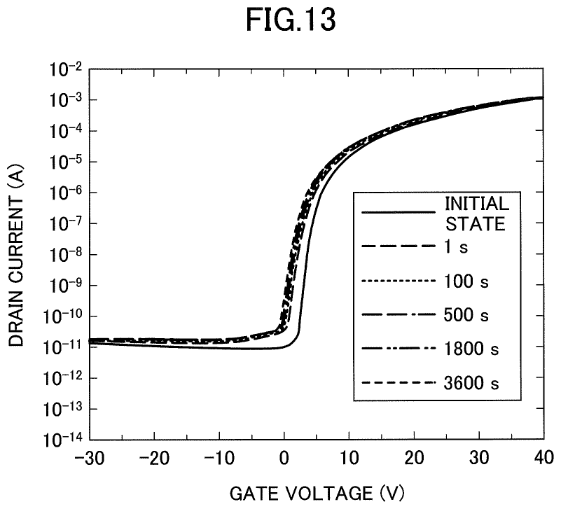

FIG. 13 illustrates an evaluation result obtained with the TFT sample 1 400.

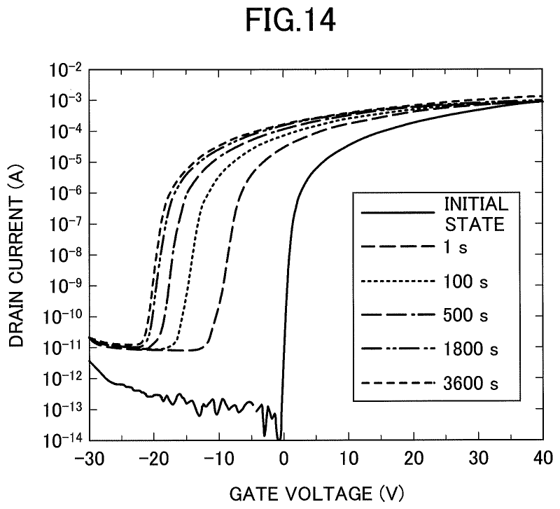

For reference, FIG. 14 illustrates an evaluation result of a TFT sample of a conventional configuration produced according to a method similar to the TFT sample 1 400. For the TFT sample of the conventional configuration, an IGZO compound was used as a semiconductor layer. The IGZO compound had a composition in which In:Ga:Zn was 40:36:24 by atomic ratio.

In FIG. 13 and FIG. 14, a line in the “initial state” denotes a measurement result in a dark state, i.e., a state without illumination stress.

It was found from FIG. 14 that, in a case of a TFT sample using an IGZO compound as a semiconductor layer, the characteristics changed significantly under negative bias illumination stress. For example, it was found that, in a case where this TFT sample was kept for 3600 seconds under the negative bias illumination stress, the gate voltage at which the drain current rises greatly shifted to the negative side as compared with the initial state.

It was found from FIG. 14 that a difference ΔVₜₕ(=V_{th (2)}−Vₜₕ₍₁₎) between a threshold voltage Vₜₕ₍₁₎ obtained when the TFT sample was held for one second under negative bias illumination stress and a threshold voltage Vₜₕ₍₂₎ obtained when the TFT sample was kept for 3600 seconds under the negative bias illumination stress was −10.4 V. The difference ΔVₜₕ will be hereinafter referred to as a “threshold voltage difference”.

The threshold voltage Vₜₕ₍₁₎ can be obtained from the following expression (2) in a saturation region of the TFT sample 1 400:

I_{d}=α×μC_{Ox}×½(V_{gs}−Vₜₕ₍₁₎)² Expression (2)

Herein, I_{d} denotes a drain current, μ denotes a field effect mobility, C_{Ox} denotes a capacitance per unit area formed by the gate electrode and the semiconductor layer 430, and V_{gs} denotes a voltage between the gate electrode and the source electrode 450. α can be expressed as W/Lt, for example, where the length of the semiconductor layer 430 is denoted as Lt, and the width is denoted as W.

The above is also applicable to Vₜₕ₍₂₎.

In contrast, it was found from FIG. 13 that characteristics of the TFT sample 1 400 including the film as the semiconductor layer 430 did not appreciably change even after the semiconductor layer 430 was kept for 3600 seconds under the negative bias illumination stress.

In the TFT sample 1 400, the threshold voltage difference ΔVₜₕ was −0.75 V.

It was found that a fluctuation in characteristics of the film 1 was significantly reduced in this manner even under the negative bias illumination stress. It should be noted that the field effect mobility of the film 1 calculated from the saturation region characteristics of the TFT sample 1 in a dark state was 18.8 cm²V⁻¹ s⁻¹.

### Example 2

(Evaluation of Semiconductor Compound Film)

According to a method similar to Example 1, a semiconductor compound film was formed, and an evaluation thereof was performed.

However, in this Example 2, a target for sputtering deposition was prepared as follows.

A mixed powder was prepared by weighing and mixing Ga₂O₃ powder, ZnO powder, and SnO₂ powder, so that a cation atom % ratio of Ga:Zn:Sn becomes 20:56.7:23.3. Further, 1 mol % of calcium fluoride (CaF₂) powder was added to this powder to prepare a mixed powder. Then, a green compact was formed from the obtained mixed powder. Then, the green compact was fired to obtain a sintered body having a diameter of 50.8 mm and a height of 5 mm (hereinafter referred to as a “second sintered body”).

Using the second sintered body as the target, the thin film was deposited on the substrate by sputtering method. A quartz glass substrate was used as the substrate.

Thereafter, a glass substrate (hereinafter referred to as a “second glass substrate sample”) formed with the semiconductor compound film was produced according to a method similar to Example 1.

As a result of performing X-ray diffraction measurement of a film (hereinafter referred to as a “film 2”) using the second glass substrate sample, the film 2 was determined to be amorphous.

(Production and Evaluation of TFT Sample)

Subsequently, a TFT device (hereinafter referred to as a “TFT sample 2”) was produced by a method similar to the TFT sample 1 in the above-described Example 1. In the TFT sample 2, however, the semiconductor layer was the film 2.

An evaluation of characteristics of the obtained TFT sample 2 was performed by a method similar to Example 1 under negative bias illumination stress.

As a result, it was found that characteristics did not appreciably change even after the TFT sample 2 was kept for 3600 seconds under the negative bias illumination stress.

When the threshold voltage difference ΔVₜₕ was derived by the above-described method, the threshold voltage difference ΔVₜₕ was determined to be −0.75 V.

It was found that a fluctuation in characteristics of the film 2 was significantly reduced in this manner even under the negative bias illumination stress. It should be noted that the field effect mobility of the film 2 calculated from the saturation region characteristics of the TFT sample 2 in a dark state was 14.0 cm²V⁻¹ s⁻¹.

### Example 3

(Evaluation of Semiconductor Compound Film)

According to a method similar to Example 1, a semiconductor compound film was formed, and an evaluation thereof was performed.

However, in this Example 3, a target for sputtering deposition was prepared as follows.

A mixed powder was prepared by weighing and mixing Ga₂O₃ powder, ZnO powder, and SnO₂ powder, so that a cation atom % ratio of Ga:Zn:Sn becomes 26.7:53.3:20. Further, 1 mol % of calcium fluoride (CaF₂) powder was added to this powder to prepare a mixed powder. Then, a green compact was formed from the obtained mixed powder. Then, the green compact was fired to obtain a sintered body having a diameter of 50.8 mm and a height of 5 mm (hereinafter referred to as a “third sintered body”).

Using the third sintered body as the target, the thin film was deposited on the substrate by sputtering method. A quartz glass substrate was used as the substrate.

Thereafter, a glass substrate (hereinafter referred to as a “third glass substrate sample”) formed with the semiconductor compound film was produced according to a method similar to Example 1.

As a result of performing X-ray diffraction measurement of a film (hereinafter referred to as a “film 3”) using the third glass substrate sample, the film 3 was determined to be amorphous.

(Production and Evaluation of TFT Sample)

Subsequently, a TFT device (hereinafter referred to as a “TFT sample 3”) was produced by a method similar to the TFT sample 1 in the above-described Example 1. In the TFT sample 3, however, the semiconductor layer was the film 3.

An evaluation of characteristics of the obtained TFT sample 3 was performed by a method similar to Example 1 under negative bias illumination stress.

As a result, it was found that characteristics did not appreciably change even after the TFT sample 3 was kept for 3600 seconds under the negative bias illumination stress.

When the threshold voltage difference ΔVₜₕ was derived by the above-described method, the threshold voltage difference ΔVₜₕ was determined to be −0.53 V.

It was found that a fluctuation in characteristics of the film 3 was significantly reduced in this manner even under the negative bias illumination stress. It should be noted that the field effect mobility of the film 3 calculated from the saturation region characteristics of the TFT sample 3 in a dark state was 11.8 cm²V⁻¹ s⁻¹.

### Example 4

(Evaluation of Semiconductor Compound Film)

According to a method similar to Example 1, a semiconductor compound film was formed, and an evaluation thereof was performed.

However, in this Example 4, a target for sputtering deposition was prepared as follows.

A mixed powder was prepared by weighing and mixing Ga₂O₃ powder, ZnO powder, and SnO₂ powder, so that a cation atom % ratio of Ga:Zn:Sn becomes 33.3:50:16.7. Further, 1 mol % of calcium fluoride (CaF₂) powder was added to this powder to prepare a mixed powder. Then, a green compact was formed from the obtained mixed powder. Then, the green compact was fired to obtain a sintered body having a diameter of 50.8 mm and a height of 5 mm (hereinafter referred to as a “fourth sintered body”).

Using the fourth sintered body as the target, the thin film was deposited on the substrate by sputtering method. A quartz glass substrate was used as the substrate.

Thereafter, a glass substrate (hereinafter referred to as a “fourth glass substrate sample”) formed with the semiconductor compound film was produced according to a method similar to Example 1.

As a result of performing X-ray diffraction measurement of a film (hereinafter referred to as a “film 4”) using the fourth glass substrate sample, the film 4 was determined to be amorphous.

(Production and Evaluation of TFT Sample)

Subsequently, a TFT device (hereinafter referred to as a “TFT sample 4”) was produced by a method similar to the TFT sample 1 in the above-described Example 1. In the TFT sample 4, however, the semiconductor layer was the film 4.

An evaluation of characteristics of the obtained TFT sample 4 was performed by a method similar to Example 1 under negative bias illumination stress.

As a result, it was found that characteristics did not appreciably change even after the TFT sample 4 was kept for 3600 seconds under the negative bias illumination stress.

When the threshold voltage difference ΔVₜₕ was derived by the above-described method, the threshold voltage difference ΔVₜₕ was determined to be −0.37 V.

It was found that a fluctuation in characteristics of the film 4 was significantly reduced in this manner even under the negative bias illumination stress. It should be noted that the field effect mobility of the film 4 calculated from the saturation region characteristics of the TFT sample 4 in a dark state was 9.7 cm²V⁻¹ s⁻¹.

### Example 5

(Evaluation of Semiconductor Compound Film)

According to a method similar to Example 1, a semiconductor compound film was formed, and an evaluation thereof was performed.

However, in this Example 5, a target for sputtering deposition was prepared as follows.

A mixed powder was prepared by weighing and mixing Ga₂O₃ powder, ZnO powder, and SnO₂ powder, so that a cation atom % ratio of Ga:Zn:Sn becomes 13.3:60:26.7. Further, 1 mol % of magnesium fluoride (MgF₂) powder was added to this powder to prepare a mixed powder. Then, a green compact was formed from the obtained mixed powder. Then, the green compact was fired to obtain a sintered body having a diameter of 50.8 mm and a height of 5 mm (hereinafter referred to as a “fifth sintered body”).

Using the fifth sintered body as the target, the thin film was deposited on the substrate by sputtering method. A quartz glass substrate was used as the substrate.

Thereafter, a glass substrate (hereinafter referred to as a “fifth glass substrate sample”) formed with the semiconductor compound film was produced according to a method similar to Example 1.

As a result of performing X-ray diffraction measurement of a film (hereinafter referred to as a “film 5”) using the fifth glass substrate sample, the film 5 was determined to be amorphous.

(Production and Evaluation of TFT Sample)

Subsequently, a TFT device (hereinafter referred to as a “TFT sample 5”) was produced by a method similar to the TFT sample 1 in the above-described Example 1. In the TFT sample 5, however, the semiconductor layer was the film 5.

An evaluation of characteristics of the obtained TFT sample 5 under the negative bias illumination stress was performed by a method similar to Example 1.

As a result, it was found that characteristics did not appreciably change even after the TFT sample 5 was kept for 3600 seconds under the negative bias illumination stress.

When the threshold voltage difference ΔVₜₕ was derived by the above-described method, the threshold voltage difference ΔVₜₕ was determined to be −1.21 V.

It was found that a fluctuation in characteristics of the film 5 was significantly reduced in this manner even under the negative bias illumination stress. It should be noted that the field effect mobility of the film 5 calculated from the saturation region characteristics of the TFT sample 5 in a dark state was 18.5 cm²V⁻¹ s⁻¹.

### Example 6

(Evaluation of Semiconductor Compound Film)

According to a method similar to Example 1, a semiconductor compound film was formed, and an evaluation thereof was performed.

However, in this Example 6, a target for sputtering deposition was prepared as follows.

A mixed powder was prepared by weighing and mixing Ga₂O₃ powder, ZnO powder, and SnO₂ powder, so that a cation atom % ratio of Ga:Zn:Sn becomes 33.3:50:16.7. Further, 1 mol % of magnesium fluoride (MgF₂) powder was added to this powder to prepare a mixed powder. Then, a green compact was formed from the obtained mixed powder. Then, the green compact was fired to obtain a sintered body having a diameter of 50.8 mm and a height of 5 mm (hereinafter referred to as a “sixth sintered body”).

Using the sixth sintered body as the target, the thin film was deposited on the substrate by sputtering method. A quartz glass substrate was used as the substrate.

Thereafter, a glass substrate (hereinafter referred to as a “sixth glass substrate sample”) formed with the semiconductor compound film was produced according to a method similar to Example 1.

As a result of performing X-ray diffraction measurement of the film (hereinafter referred to as a “film 6”) on the sixth glass substrate sample, the film 6 was determined to be amorphous.

(Production and Evaluation of TFT Sample)

Subsequently, a TFT device (hereinafter referred to as a “TFT sample 6”) was produced by a method similar to the TFT sample 1 in the above-described Example 1. In the TFT sample 6, however, the semiconductor layer was the film 6.

An evaluation of characteristics of the obtained TFT sample 6 under the negative bias illumination stress was performed by a method similar to Example 1.

As a result, it was found that characteristics did not appreciably change even after the TFT sample 6 was kept for 3600 seconds under the negative bias illumination stress.

When the threshold voltage difference ΔVₜₕ was derived by the above-described method, the threshold voltage difference ΔVₜₕ was determined to be −0.32 V.

It was found that a fluctuation in characteristics of the film 6 was significantly reduced in this manner even under the negative bias illumination stress. It should be noted that the field effect mobility of the film 6 calculated from the saturation region characteristics of the TFT sample 6 in a dark state was 11.1 cm²V⁻¹ s⁻¹.

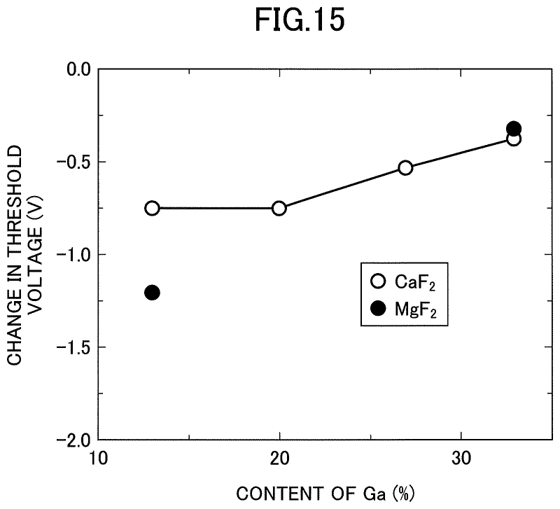

FIG. 15 illustrates the threshold voltage difference ΔVₜₕ obtained with each TFT sample. In FIG. 15, the horizontal axis indicates the amount (atom %) of Ga contained in the semiconductor layer of a TFT sample, and the vertical axis indicates the threshold voltage difference ΔVₜₕ.

It was found from FIG. 15 that, of the TFT samples 1 to 6, even the largest absolute value of the obtained threshold voltage difference ΔVₜₕ was less than 1.5 V, which is significantly smaller than an absolute value (10.4 V) of a threshold voltage difference ΔVₜₕ of a conventional TFT sample.

In this manner, it was found that fluctuations in the characteristics of the TFT samples 1 to 6 including the semiconductor compound according to the embodiment of the present invention were significantly reduced even under the negative bias illumination stress. Furthermore, it was found that the TFT samples 1 to 6 exhibited high field effect mobilities even in a state in which the fluctuations in characteristics are significantly reduced.

### Example 7

(Production of Semiconductor Compound Film)

A mixed powder was prepared by weighing and mixing In₂O₃ powder, Ga₂O₃ powder, and ZnO powder, so that a cation atom % ratio of In:Ga:Zn becomes 1:1:1. A green compact was formed from the obtained mixed powder. Then, the green compact was fired to obtain a sintered body (hereinafter referred to as a “seventh sintered body”).

Using the seventh sintered body as a target, a film was deposited onto the substrate by pulsed laser deposition (PLD).

A KrF excimer laser (A=248 nm, produced by Coherent, Inc.) was used as a laser light source. The power of the KrF laser was 95 mJ, and the distance between the substrate and the target was about 30 mm. The back pressure of the vacuum chamber was 6.0×10⁻⁵ Pa.

Three gas supply lines were provided in the vacuum chamber. A reactant gas was supplied to the vacuum chamber from each gas supply line. The first gas supply line was supplied with oxygen gas, the second gas supply line was supplied with argon gas, and the third gas supply line was supplied with a mixed gas of argon and fluorine gas (Ar/F₂ gas).

The pressure in the vacuum chamber was 5 Pa. The concentration of oxygen gas was 97%, and the concentration of fluorine gas was 40 ppm.

After deposition, the substrate was heat-treated in oxygen gas. The temperature of the heat treatment was 300 degrees Celsius, and the heat treatment was performed for one hour.

As a result, a film was formed on the substrate. Hereinafter, the obtained film is referred to as a “film 7”.

For comparison, a film was prepared by a method similar to the above without introducing F₂ gas into the vacuum chamber during deposition (i.e., the concentration of fluorine gas was almost zero). The obtained film is referred to as a “first fluorine-free film”.

(Evaluation of Semiconductor Compound Film)

(Fluorine Concentration)

EPMA measurement was performed on the obtained film, and the fluorine concentration in the film was evaluated.

As a result, in the film 7, C_{F}/(C_{O}+C_{F}) value was 8.9%. Herein, C_{F} represents a concentration (cm⁻³) of fluorine included in the film, and C_{O} represents a concentration (cm⁻³) of oxygen included in the film.

In the first fluorine-free film, F was not detected in the film, and C_{F}/(C_{O}+C_{F}) value was zero.

(H⁻ Concentration)

FTIR measurement was performed on the obtained film to evaluate hydride ion H⁻ concentration.

As a result, in the film 7, the H⁻ concentration was 1.1×10¹⁹ cm⁻³. In the first fluorine-free film, the H⁻ concentration was 6.9×10¹⁹ cm⁻³.

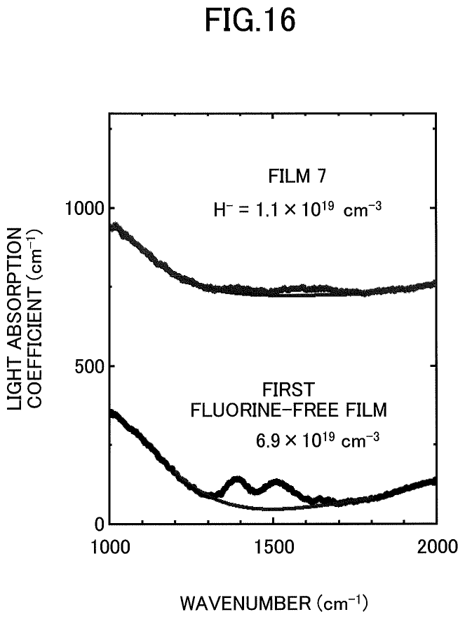

FIG. 16 illustrates a result of FTIR measurement obtained with both of the films.

In this manner, it was found that the hydride ion H⁻ concentration can be reduced by introducing fluorine into the IGZO compound.

(OH Concentration and Density)

FTIR measurement was performed on the obtained film to measure the OH concentration.

As a result, in the film 7, the OH concentration was 6.0×10²⁰ cm⁻³. In the first fluorine-free film, the OH concentration was 8.6×10²⁰ cm⁻³.

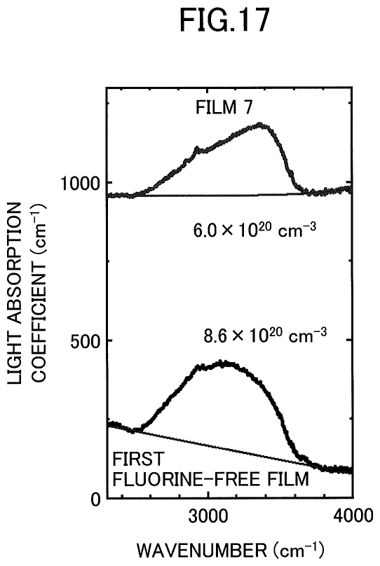

FIG. 17 illustrates a result of FTIR measurement. In any of these films, the density was equal to or more than 6.0 gcm⁻³.

(Light Absorption Characteristics)

With regard to the obtained film, the light absorption characteristics were evaluated.

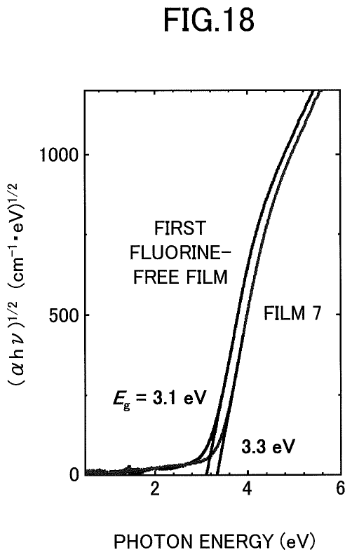

FIG. 18 illustrates light absorption characteristics of the film 7 and the first fluorine-free film.

The optical band gap of the first fluorine-free film was estimated to be 3.1 eV. In contrast, the optical band gap of the film 7 was 3.3 eV, which was significantly higher than that of the first fluorine-free film.

(Production and Evaluation of TFT Sample)

Subsequently, by a method similar to the TFT sample 1 in the above-described Example 1, a TFT device (hereinafter referred to as a “TFT sample 7”) was prepared.

In the TFT sample 7, however, the semiconductor layer was the film 7. The thickness of the semiconductor layer was 40 nm, and the source and drain electrodes were Ti. Further, the anneal condition of the silicon substrate was 300 degrees Celsius for one hour.

An evaluation of characteristics of the obtained TFT sample 7 under the negative bias illumination stress was performed by a method similar to Example 1. With the TFT sample 7, however, the voltage applied to the gate electrode was set to −40 V.

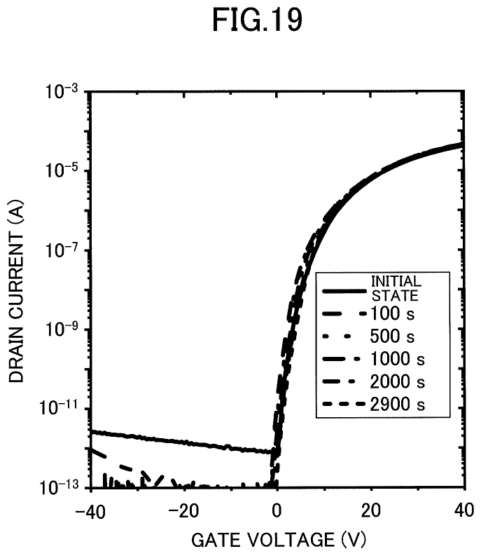

FIG. 19 illustrates an evaluation result obtained with the TFT sample 7.

As illustrated in this figure, it was found that characteristics of the TFT sample 7 did not appreciably change even after the TFT sample 7 was held for 2900 seconds under the negative bias illumination stress.

When the threshold voltage difference ΔVₜₕ was derived by the above-described method, the threshold voltage difference ΔVₜₕ was determined to be +1.16 V.

For comparison, a TFT film was prepared by a method similar to the above using the above-described “first fluorine-free film” as a semiconductor layer. Hereinafter, this TFT sample is referred to as a “TFT sample according to a comparative example”. An evaluation of characteristics of the TFT sample according to the comparative example was performed under the negative bias illumination stress.

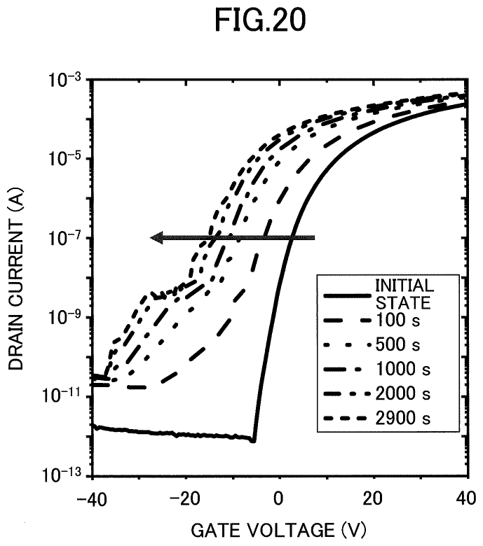

FIG. 20 illustrates an evaluation result obtained with the TFT sample according to the comparative example.

It was found from this result that, in the case of the TFT sample according to the comparative example using the IGZO compound as the semiconductor layer, characteristics greatly change under the negative bias illumination stress.

It was found that a fluctuation in characteristics of the film 7 was significantly reduced in this manner even under the negative bias illumination stress. The field effect mobility of the film 7 calculated from the saturation region characteristics of the TFT sample 7 in a dark state was 0.6 cm²V⁻¹ s⁻¹.

### Example 8

(Production of Semiconductor Compound Film)

According to a method similar to Example 1, a semiconductor compound film was prepared.

However, in this Example 8, a target for sputtering deposition was prepared as follows.

A mixed powder was prepared by weighing and mixing In₂O₃ powder, Ga₂O₃ powder, and ZnO powder, so that a cation atom % ratio of In:Ga:Zn becomes 1:1:1. Then, calcium fluoride (CaF₂) powder was added to this powder to prepare a mixed powder. The calcium fluoride was added so that, in the prepared composition, C_{F}/(C_{O}+C_{F}) value becomes 0.5%.

Subsequently, a green compact was formed from the obtained mixed powder. Then, the green compact was fired to obtain a sintered body (hereinafter referred to as a “sintered body 8-1”) having a diameter of 50.8 mm and a height of 5 mm.

According to a method similar to the above, a sintered body (hereinafter referred to as a “sintered body 8-2”) was obtained from the mixed powder. In the case of this sintered body 8-2, however, the calcium fluoride in the mixed powder was added so that, in the prepared composition, C_{F}/(C_{O}+C_{F}) value becomes 1.5%.

By using the sintered bodies as the target, a film was deposited on the substrate by the sputtering method. A glass substrate was used as the substrate.

As the sputter apparatus, MiniLab 060A (Moorfield Nanotechnology Limited) was used, and the deposition was performed while the substrate was rotated at 23 rpm. The power supply was set to RF 150 W, and the back pressure of the vacuum chamber was set to 2×10⁻⁵ Pa.

The pressure in the vacuum chamber was 0.5 Pa. Using Ar/O₂ mixed gas, the oxygen concentration was adjusted to 3%.

As a result, a film was formed on the substrate. A film obtained with the sintered body 8-1 used as the target is referred to as a “film 8-1”, and a film obtained with the sintered body 8-2 used as the target is referred to as a “film 8-2”.

The X-ray diffraction measurement was performed on both of the obtained films. As a result, it was found that both of the film 8-1 and the film 8-2 were amorphous.

(Evaluation of Semiconductor Compound Film)

With respect to both of the obtained films, the following evaluation was performed.

(F Concentration, H⁻ Concentration, and OH Concentration)

The F concentrations in both of the films were measured by EPMA method. As a result of analysis, a C_{F}/(C_{O}+C_{F}) value in the film 8-1 was 0.27%. In contrast, a C_{F}/(C_{O}+CO value in the film 8-2 was 1.5%. In either of the films, the distribution of fluorine in the film was substantially uniform.

With the FTIR measurement, the hydride ion H⁻ concentrations in both of the films were evaluated. As a result, in either of the films, the hydride ion H⁻ concentration was estimated as equal to or less than 5×10¹⁹ cm⁻³.

With the FTIR measurement, the OH concentrations in both of the films were evaluated. As a result, in any of these films, the OH concentration was estimated as equal to or less than 1×10²¹ cm⁻³.

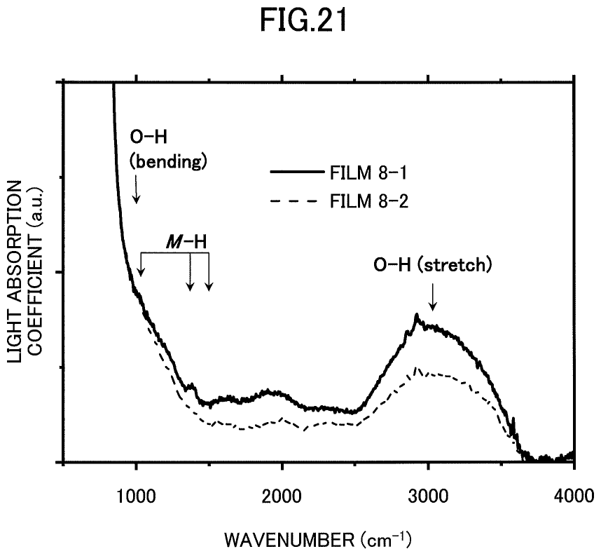

FIG. 21 illustrates a measurement result of FTIR obtained with both of the films.

(Production and Evaluation of TFT Samples)

Subsequently, by a method similar to the TFT sample 1 in the above-described Example 1, a TFT device was prepared.

However, herein, the semiconductor layers were the “film 8-1” and the “film 8-2”. Hereinafter, a TFT device having the film 8-1 as the semiconductor layer is referred to as a “TFT sample 8-1”, and a TFT device having the film 8-2 as the semiconductor layer is referred to as a “TFT sample 8-2”.

The oxygen concentration during deposition of the semiconductor layer was set to 3%.

An evaluation of characteristics of the obtained TFT sample 8-1 and the obtained TFT sample 8-2 under the negative bias illumination stress was performed by a method similar to Example 1. However, herein, the voltage applied to the gate electrode was set to −30 V.

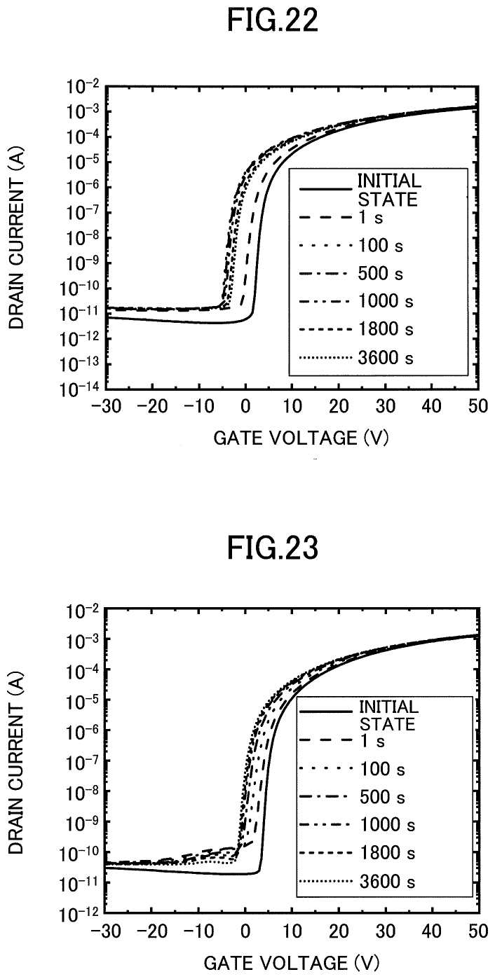

FIG. 22 illustrates an evaluation result obtained with the TFT sample 8-1. FIG. 23 illustrates an evaluation result obtained with the TFT sample 8-2.

It was found from the comparison between FIGS. 22 and 23 and FIG. 20 explained above that characteristics of the TFT sample 8-1 and the TFT sample 8-2 did not appreciably change even after the TFT sample 8-1 and the TFT sample 8-2 were kept for 3600 seconds under the negative bias illumination stress.

When the threshold voltage difference ΔVₜₕ was derived by the above-described method, the threshold voltage difference ΔVₜₕ in the TFT sample 8-1 was determined to be −5.0 V. The threshold voltage difference ΔVₜₕ of the TFT sample 8-2 was determined to be −5.0 V.

It was found that fluctuations in characteristics of the film 8-1 and the film 8-2 were significantly reduced in this manner even under the negative bias illumination stress. The field effect mobility of the film 8-1 calculated from the saturation region characteristics of the TFT sample 8-1 in a dark state was 12.2 cm²V¹ s¹. The field effect mobility of the film 8-2 calculated from the saturation region characteristics of the TFT sample 8-2 in a dark state was 11.6 cm²V⁻¹ s⁻¹.

### Example 9

(Production of Semiconductor Compound Film)

A glass substrate having a semiconductor compound film was prepared by a co-sputtering method using a target made of a sintered body of IGZO compound (In:Ga:Zn=1:1:1) (hereinafter referred to as a “target A”) and a target made of LaF₃ sintered body (hereinafter referred to as a “target B”).

As the sputter apparatus, MiniLab 060A (Moorfield Nanotechnology Limited) was used, and the deposition was performed while the substrate was rotated at 23 rpm.

The power applied to the target A was set to RF 150 W. In contrast, the power applied to the target B was selected from three types, i.e., 0.08 times, 0.25 times, and 0.5 times of the power applied to the target A.

The back pressure of the vacuum chamber was set to 2×10⁻⁵ Pa.

The pressure in the vacuum chamber was 0.5 Pa. Using Ar/O₂ mixed gas, the oxygen concentration was adjusted to 3%.

Therefore, a film was formed on the substrate. The film obtained under a condition in which the power applied to the target B was 0.08 times the power applied to the target A is referred to as a “film 9-1”. The film obtained under a condition in which the power applied to the target B was 0.25 times the power applied to the target A is referred to as a “film 9-2”. The film obtained under a condition in which the power applied to the target B was 0.5 times the power applied to the target A is referred to as a “film 9-3”.

X-ray diffraction measurement was performed on the obtained three types of films. As a result, it was found that any one of the film 9-1, the film 9-2, and the film 9-3 was amorphous.

(Evaluation of Semiconductor Compound Film)

The following evaluation was performed on the obtained three types of films.

(F Concentration and Light absorption Characteristics)

The F concentration in each film was measured by EDS method. As a result of analysis, the C_{F}/(C_{O}+C_{F}) value in the film 9-1 was determined to be 2.4%. The C_{F}/(C_{O}+C_{F}) value in the film 9-2 was determined to be 5.7%. The C_{F}/(C_{O}+C_{F}) value in the film 9-3 was determined to be 9.7%.

The optical band gaps of the film 9-1 to the film 9-3 were determined to be 3.2 eV, 3.3 eV, and 3.5 eV, respectively.

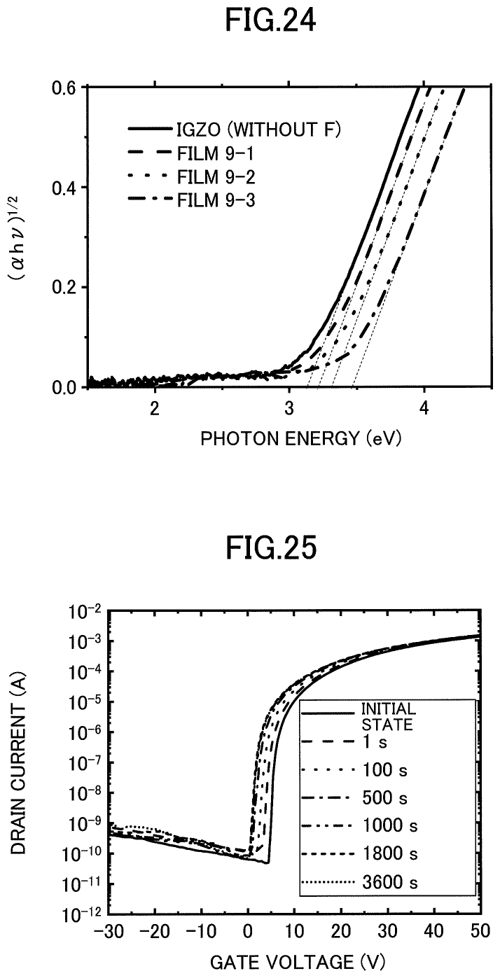

FIG. 24 illustrates light absorption spectrums obtained with the films. This figure also illustrates, for comparison, a light absorption spectrum of an IGZO compound.

(Production and Evaluation of TFT Sample)

Subsequently, a TFT device was produced by a method similar to the TFT sample 1 in the above-described Example 1.

However, herein, the semiconductor layer was the film 9-1, the film 9-2, or the film 9-3. Hereinafter, a TFT device having the film 9-1 as the semiconductor layer is referred to as a “TFT sample 9-1”, a TFT device having the film 9-2 as the semiconductor layer is referred to as a “TFT sample 9-2”, and a TFT device having the film 9-3 as the semiconductor layer is referred to as a “TFT sample 9-3”.

The oxygen concentration during the deposition of the semiconductor layer was set to 3%.

Evaluation of characteristics of the obtained TFT samples 9-1 to 9-3 under the negative bias illumination stress was performed by a method similar to Example 1. However, herein, the voltage applied to the gate electrode was set to −30 V.

FIG. 25 illustrates an evaluation result obtained with the TFT sample 9-1.

As a result of the measurement, it was found that characteristics of any of the TFT samples 9-1 to 9-3 did not appreciably change even after the TFT samples 9-1 to 9-3 were kept for 3600 seconds under the negative bias illumination stress.

When the threshold voltage difference ΔVₜₕ was derived by the above-described method, the threshold voltage difference ΔVₜₕ in the TFT sample 9-1 was determined to be −3.7 V. The threshold voltage difference ΔVₜₕ of the TFT sample 9-2 was determined to be −3.0 V. The threshold voltage difference ΔVₜₕ of the TFT sample 9-3 was determined to be +0.07 V.

It was found that a fluctuation in characteristics of the film 9-1 to the film 9-3 was significantly reduced in this manner even under the negative bias illumination stress. The field effect mobility of the film 9-1 calculated from the saturation region characteristics of the TFT sample 9-1 in a dark state was 12.2 cm²V⁻¹ The field effect mobility of the film 9-2 calculated from the saturation region characteristics of the TFT sample 9-2 in a dark state was 6.2 cm²V⁻¹ s⁻¹. The field effect mobility of the film 9-3 calculated from the saturation region characteristics of the TFT sample 9-3 in a dark state was 1.9 cm²V⁻¹ s⁻¹.

This application claims the priority based on Japanese Patent Application No. 2017-228022 filed on Nov. 28, 2017, the entire content of which is incorporated herein by reference.

What is claimed is:

1. An oxide-based semiconductor compound comprising metal cations and oxygen,
wherein hydride ions H⁻ originally bonded with the metal cations have been replaced with fluorine ions and
at least one of the fluorine ions F⁻ is bonded with one to three of the metal cations.

2. The oxide-based semiconductor compound according to claim 1, wherein a concentration of the fluorine ions F⁻ is equal to or more than 1×10¹⁷ cm⁻³, and
a concentration of the hydride ions H⁻ is equal to or less than 5×10¹⁹ cm⁻³.

3. The oxide-based semiconductor compound according to claim 1, wherein where C_{F} denotes a fluorine concentration (cm⁻³), and C_{O} denotes an oxygen concentration (cm⁻³), C_{F}/(C_{O}+C_{F}) value is in a range of 1% to 10%.

4. The oxide-based semiconductor compound according to claim 1, wherein an OH concentration is equal to or less than 1×10²¹ cm⁻³.

5. A semiconductor compound comprising:
gallium, zinc, and oxygen; and
at least one of tin, aluminum, titanium, and indium, the semiconductor compound further comprising:
fluorine.

6. The semiconductor compound according to claim 5, wherein a content of the fluorine is in a range of 0.001 mol % to 2 mol %.

7. The semiconductor compound according to claim 5, wherein an atomic ratio of gallium atoms with respect to all cationic atoms is in a range of 10% to 40%.

8. The semiconductor compound according to claim 5, comprising tin.

9. The semiconductor compound according to claim 8, wherein an atomic ratio of tin atoms with respect to all cationic atoms is in a range of 10% to 35%.

10. The semiconductor compound according to claim 5, comprising indium.

11. The semiconductor compound according to claim 10, wherein an atomic ratio of indium atoms with respect to all cationic atoms is in a range of 10% to 40%.

12. The semiconductor compound according to claim 5, wherein the semiconductor compound is amorphous.

13. A semiconductor device including a layer of a semiconductor compound,
wherein the semiconductor device is any one of a TFT (thin-film transistor), a photovoltaic cell, and an OLED (organic light emitting diode), and
the semiconductor compound is the semiconductor compound of claim 5.

14. The semiconductor device according to claim 13, comprising a substrate, the layer arranged on or above the substrate, a gate electrode arranged on or above the layer, and a source electrode and a drain electrode arranged to be in contact with the layer.

15. The semiconductor device according to claim 13, comprising a substrate, a gate electrode arranged on or above the substrate, the layer arranged on or above the gate electrode, and a source electrode and a drain electrode in contact with the layer.

16. A laminate comprising:
a substrate;
a layer of a semiconductor compound arranged on or above the substrate,
wherein the semiconductor compound is the semiconductor compound of claim 5.

17. A target for deposition, comprising the semiconductor compound of claim 5.

18. A semiconductor compound comprising:
gallium, zinc, and oxygen; and
at least one of tin, aluminum, titanium, and indium, wherein an atomic ratio of gallium atoms with respect to all cationic atoms is in a range of 10% to 40%.

19. The semiconductor compound according to claim 18, wherein a concentration of hydride ions H⁻ is equal to or less than 10¹⁹ cm⁻³.
